(19) United States
(12) Patent Application Publication
(10) Pub. No.: US 2011/0059579 A1
(43) Pub. Date: Mar. 10, 2011

(54) METHOD OF FORMING TAPE BALL GRID ARRAY PACKAGE

(75) Inventors: Poh Leng Eu, Petaling Jaya (MY); Lan Chu Tan, Klang (MY); Cheng Qiang Cui, Hong Kong (CN)

(73) Assignee: FREESCALE SEMICONDUCTOR, INC., Austin, TX (US)

(21) Appl. No.: 12/554,992

(22) Filed: Sep. 8, 2009

(51) Int. Cl. H01L 21/50

(52) U.S. Cl. 438/122; 257/E21.499

(57) ABSTRACT

A method of forming a semiconductor package including providing a substrate having a through hole formed therein. A tape is attached to a surface of the substrate such that the through hole is covered by the tape. An integrated circuit (IC) die is attached to the tape. The IC die is electrically connected to the substrate via a plurality of electrical connections. The IC die and the electrical connections are encapsulated and the tape is removed from the substrate.

### BACKGROUND OF THE INVENTION

The present invention relates to the packaging of integrated circuits (ICs) and more particularly to a method of forming a tape ball grid array (TBGA) package.

Conventional substrates for tape ball grid array (TBGA) packages are quite often provided with preformed center cavities. These preformed cavities in the TBGA substrates are typically formed via a precise etching process. Consequently, such substrates are manufactured under stringent etching process controls. This translates to higher substrate costs and correspondingly higher packaging costs. Accordingly, it would be desirable to have a less costly method of forming TBGA packages.

### BRIEF DESCRIPTION OF THE DRAWINGS

The following detailed description of preferred embodiments of the invention will be better understood when read in conjunction with the appended drawings. The present invention is illustrated by way of example and is not limited by the accompanying figures, in which like references indicate similar elements. It is to be understood that the drawings are not to scale and have been simplified for ease of understanding the invention.

FIG. 1 is an enlarged cross-sectional view of a substrate having a through hole formed therein in accordance with an embodiment of the present invention;

FIG. 2 is an enlarged cross-sectional view of an integrated circuit (IC) die attached to a tape and electrically connected to the substrate of FIG. 1;

FIG. 3 is an enlarged cross-sectional view of a tape ball grid array (TBGA) package formed in accordance with an embodiment of the present invention;

FIG. 4 is an enlarged cross-sectional view of a TBGA package formed in accordance with another embodiment of the present invention; and

FIG. 5 is a schematic flow diagram illustrating a method of forming a TBGA package in accordance with an embodiment of the present invention.

### DETAILED DESCRIPTION OF THE INVENTION

The detailed description set forth below in connection with the appended drawings is intended as a description of the presently preferred embodiments of the invention, and is not intended to represent the only form in which the present invention may be practiced. It is to be understood that the same or equivalent functions may be accomplished by different embodiments that are intended to be encompassed within the spirit and scope of the invention. In the drawings, like numerals are used to indicate like elements throughout.

The present invention provides a method of forming a semiconductor package including the step of providing a substrate having a through hole formed therein. A tape is attached to a surface of the substrate such that the through hole is covered by the tape. An integrated circuit (IC) die is attached to the tape. The IC die is electrically connected to the substrate via a plurality of electrical connections. The IC die and the electrical connections are encapsulated and the tape is removed from the substrate.

The present invention also provides a method of forming a tape ball grid array (TBGA) package including the step of providing a substrate having a through hole formed therein. A tape is attached to a surface of the substrate such that the through hole is covered by the tape. An integrated circuit (IC) die is attached to the tape. The IC die is electrically connected to the substrate via a plurality of electrical connections. The IC die and the electrical connections are encapsulated and the tape is removed from the substrate.

The present invention further provides a method of forming a tape ball grid array (TBGA) package including the step of die bonding a flip chip die to a first side of a lead frame. A tape is attached to a surface of the substrate such that the through hole is covered by the tape. An integrated circuit (IC) die is attached to an adhesive surface of the tape. The IC die is electrically connected to the substrate via a plurality of electrical connections. The IC die and the electrical connections are encapsulated and the tape is removed from the substrate such that a portion of the IC die is exposed.

The present invention also provides a substrate for a tape ball grid array (TBGA) package including a tape substrate and a stiffener attached to the tape substrate. A through hole extends through the tape substrate and the stiffener. A tape is attached to a surface of the substrate and extends across the through hole. A cavity for receiving an integrated circuit (IC) die is defined by walls of the through hole and a portion of the tape extending across the through hole.

The present invention further provides a tape ball grid array (TBGA) package including a substrate having a through hole formed therein. An integrated circuit (IC) die is received in the through hole. A plurality of electrical connections electrically connects the IC die to the substrate. An encapsulant encapsulates the IC die and the electrical connections. A portion of an inactive surface of the IC die is not encapsulated or not covered with the encapsulant. A plurality of solder balls is attached to the substrate.

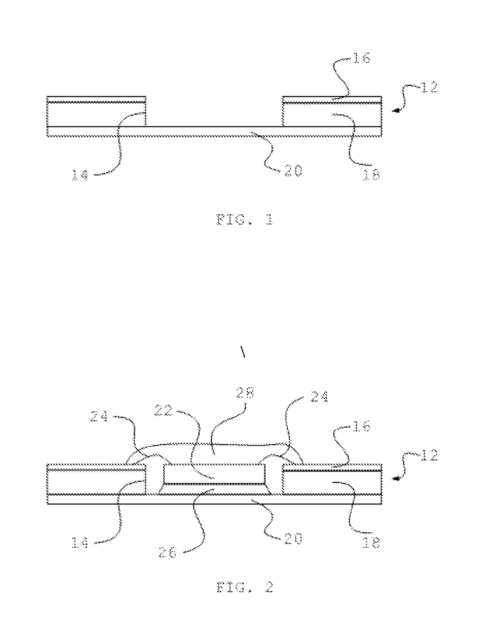

FIGS. 1 through 3 are enlarged cross-sectional views that illustrate a method of forming a semiconductor package 10 in accordance with an embodiment of the present invention.

Referring now to FIG. 1, a substrate 12 having a through hole 14 formed therein is provided. The substrate 12 comprises a tape substrate 16 having a stiffener 18 attached thereto. The through hole 14 extends through the tape substrate 16 and the stiffener 18 and is covered by a tape 20 attached to a surface of the substrate 12.

The substrate 12 with the through hole 14 may be preformed. The substrate 12 may have a thickness of between about 0.882 millimeters (mm) and about 1.042 mm.

The through hole 14 in the substrate 12 may be formed by one of stamping and etching. Advantageously, this eliminates the precise etching process required for forming the cavities in conventional TBGA substrates. Further advantageously, this also allows standardization of the tape substrate 12 according to package size, as opposed to customization required for conventional TBGA substrates. Both these advantages contribute to a substantial reduction in substrate costs and, consequently, overall package costs. In the present embodiment, the through hole 14 is substantially square-shaped and is formed in a substantially central portion of the substrate 12. However, it should be understood by those of ordinary skill in the art that the present invention is not limited by the shape of the through hole 14 or the location of the through hole 14 in the substrate 12.

The tape substrate 16 may comprise a flex tape and may be made of a polyimide material. Such tape substrates are known by those of skill in the art and are readily commercially available. The tape substrate 16 may have a thickness of between about 0.10 mm and about 0.25 mm.

The stiffener 18 is preferably made of a thermally conductive material such as, for example, copper or aluminum. Advantageously, in such an embodiment, the stiffener 18 functions as a heat spreader and helps to dissipate heat generated by the IC die 22. The stiffener 18 may have a thickness of between about 0.682 mm and about 0.842 mm.

The tape 20 attached to the substrate 12 is preferably a high temperature tape that is able to withstand temperatures greater than about 200 degrees Celsius (° C.). Such tapes are known by those of skill in the art and are readily commercially available. The tape 20 may have a thickness of between about 0.05 mm and about 0.20 mm. In the embodiment shown, the tape 20 is attached to the stiffener 18. However, it should be understood by those of skill in the art that the present invention is not limited by the surface of the substrate 12 to which the tape 20 is attached. For example, the tape 20 may instead be attached to the tape substrate 16 in an alternative embodiment. The tape 20 may partially, substantially completely or completely cover the through hole 14.

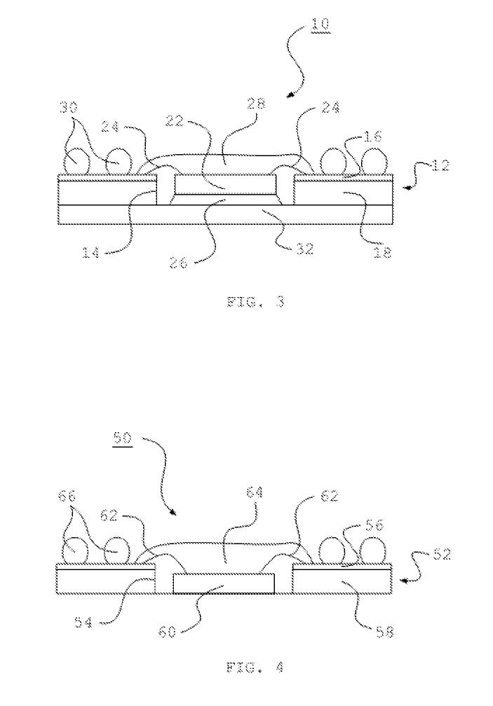

Referring now to FIG. 2, an integrated circuit (IC) die 22 is located in the through hole and attached to the tape 20. The IC die 22 is electrically connected to the substrate 12 via a plurality of electrical connections 24. In the embodiment shown, the IC die 22 is attached to the tape 20 with a die attach adhesive 26. The IC die 22 and the electrical connections 24 are encapsulated with an encapsulant 28.

The IC die 22 is received in a cavity defined by walls of the through hole 14 in the substrate 12 and the portion of the tape 20 extending across, and thereby covering, the through hole 14. The IC die 22 may be any type of circuit such as, for example, a digital signal processor (DSP) or a special function circuit. Moreover, the IC die 22 is not limited to a particular technology such as CMOS, or derived from any particular wafer technology. Further, the present invention can accommodate IC dice of various sizes; for example, in one embodiment, the IC die 22 may be about 15 mm by about 15 mm in size.

In the embodiment shown, the IC die 22 is electrically connected to the substrate 12 via a plurality of wires 24. The wires 24 may be made of gold (Au), copper (Cu), aluminum (Al) or other electrically conductive materials as are known in the art and commercially available. A known wire bonding process may be used to form the electrical connections 24.

The die attach adhesive 26 may be a liquid epoxy. Such epoxies are known in the art and commercially available. In such an embodiment, the IC die 22 is attached to the tape 20 by dispensing the die attach adhesive 26 onto a bonding site on the tape 20, placing the IC die 22 on the bonding site, and curing the die attach adhesive 26.

A well known encapsulation process such as, for example, glob top encapsulation may be performed to encapsulate the IC die 22 and the electrical connections 24. At least a portion of the back or inactive surface of the IC die 22 is not covered by the encapsulant 28. The encapsulant 28 may comprise a well known commercially available molding material such as plastic or epoxy.

Referring now to FIG. 3, the tape 20 is removed from the substrate 12 and a plurality of solder balls 30 is attached to the substrate 12 to form a tape ball grid array (TBGA) package 10. In the embodiment shown, a heat sink 32 is attached to the IC die 22 subsequent to the removal of the tape 20 from the substrate 12.

The tape 20 may be peeled off before the solder balls 30 are attached to the substrate 12. Removal of the tape 20 from the substrate 12 exposes a back portion or inactive surface of the IC die 22, in the present embodiment, under the die attach adhesive 26.

The solder balls 30 may comprise any suitable material including a lead/tin (Pb/Sn) alloy, or a lead-free solder such as tin/gold/copper (Sn/Ag/Cu) or indium antimonide (InSb). The solder balls 30 may be attached to the substrate 12 using known solder ball attach processes.

The heat sink 32 may be attached to the exposed portion of the IC die 22 with a well known commercially available adhesive gel. Attachment of the heat sink 32 to the IC die 22 enhances heat dissipation from the IC die 22 and thermal performance of the TBGA package 10.

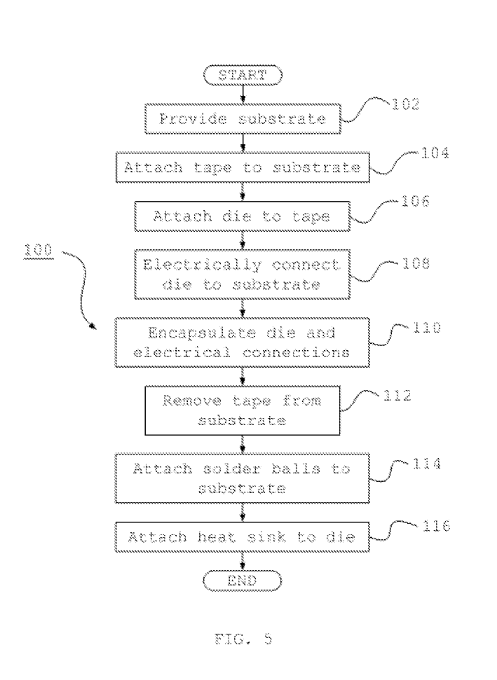

Referring now to FIG. 4, a TBGA package 50 formed in accordance with another embodiment of the present invention is shown. The TBGA package 50 includes a substrate 52 having a through hole 54 formed therein. The substrate 52 comprises a tape substrate 56 having a stiffener 58 attached thereto. The through hole 54 extends through the tape substrate 56 and the stiffener 58. An IC die 60 is electrically connected to the substrate 52 via a plurality of electrical connections 62. The IC die 60 and the electrical connections 62 are encapsulated with an encapsulant 64. A plurality of solder balls 66 is attached to the substrate 52.

The TBGA package 50 may be formed using similar materials and in a manner similar to that described in respect of the TBGA package 10 of FIG. 3. Accordingly, detailed description of the formation of the TBGA package 50 is not required for a complete understanding of the present invention. It should be noted, however, that unlike the earlier embodiment where a die attach adhesive is used, the IC die 60 of the present embodiment is directly attached to an adhesive surface of a tape (not shown) covering the through hole 54 of the substrate 52 during the packaging process. Consequently, a back portion or inactive surface of the IC die 60 is not covered by the encapsulant 64 and is thus directly exposed when the tape to which the IC die 60 is attached is removed from the substrate 12.

Referring now to FIG. 5, a schematic flow diagram illustrating a method 100 of forming a TBGA package in accordance with an embodiment of the present invention is shown. The method 100 begins at step 102 with the provision of a substrate having a through hole formed therein. At step 104, a tape is attached to a surface of the substrate such that the through hole is covered by the tape. At step 106, an integrated circuit (IC) die is attached to the tape. The IC die is electrically connected to the substrate via a plurality of electrical connections at step 108. At step 110, the IC die and the electrical connections are encapsulated. The tape is removed from the substrate at step 112. At step 114, a plurality of solder balls is attached to the substrate. A heat sink may be attached to the IC die subsequent to the removal of the tape from the substrate at step 116.

As is evident from the foregoing discussion, the present invention provides a less costly method of forming TBGA packages by using a substrate with a through hole formed therein. By doing so, the precise etching process required for forming cavities in conventional TBGA substrates may be eliminated. This also allows for standardization of the substrate according to package size, as opposed to customization required for conventional TBGA substrates. These advantages contribute to a substantial reduction in substrate costs and, consequently, overall package costs. Further advantageously, the present invention is manufacturable, as it can be implemented with existing equipment and processes.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For instance, in an alternative embodiment to the one described above, an IC die may be attached to a tape before attaching a substrate with a through hole formed therein to the tape, for example, by using a vision system to assist with substrate placement relative to the position of the die on the tape. It is understood, therefore, that this invention is not limited to the particular embodiments disclosed, but covers modifications within the spirit and scope of the present invention as defined by the appended claims.

1. A method of forming a semiconductor package, comprising:
providing a polyimide tape substrate having a through hole formed therein;
attaching a tape to a first surface of the substrate, wherein the through hole is covered by the tape;
attaching an integrated circuit (IC) die to the tape, wherein an inactive surface of the die is attached to the tape;
electrically connecting the IC die to the substrate via a plurality of electrical connections, wherein the electrical connections comprise bond wires that extend between die pads on an active surface of the IC die and a second surface of the substrate, wherein the inactive surface of the IC die opposes the active surface of the IC die and the first surface of the substrate opposes the second surface of the substrate;
encapsulating the active surface of the IC die and the electrical connections via a glob top encapsulation process;
attaching a plurality of solder balls to the second surface of the substrate, wherein the solder balls by way of the bond wires provide paths for electrical signals to the IC die; and
removing the tape from the substrate.

2. (canceled)

3. (canceled)

4. The method of forming a semiconductor package of claim 1, wherein the substrate further comprises a stiffener attached to the substrate between the substrate and the tape.

5. The method of forming a semiconductor package of claim 4, wherein the stiffener is made of a thermally conductive material.

6. The method of forming a semiconductor package of claim 4, wherein the tape is attached to the stiffener.

7. The method of forming a semiconductor package of claim 1, wherein the tape is a high temperature tape that is able to withstand temperatures greater than about 200 degrees Celsius (° C.).

8. The method of forming a semiconductor package of claim 1, wherein the IC die is attached to an adhesive surface of the tape.

9. The method of forming a semiconductor package of claim 1, wherein the IC die is attached to the tape with a die attach adhesive.

10. The method of forming a semiconductor package of claim 1, further comprising attaching a heat sink to the inactive surface of the IC die subsequent to the removal of the tape from the substrate.

11. (canceled)

12. A method of forming a tape ball grid array (TBGA) package, comprising:
providing a polyimide tape substrate having a through hole formed therein;
attaching a tape to a first surface of the substrate, wherein the through hole is covered by the tape;
attaching an inactive surface of an integrated circuit (IC) die to the tape;
electrically connecting the IC die to the substrate via a plurality of electrical connections, wherein the electrical connections comprise bond wires that extend between die pads on an active surface of the IC die and a second surface of the substrate, wherein the inactive surface of the IC die opposes the active surface of the IC die and the first surface of the substrate opposes the second surface of the substrate;
encapsulating the active surface of the IC die and the electrical connections with a glob top encapsulation process;
attaching a plurality of solder balls to the second surface of the substrate, wherein the solder balls by way of the bond wires provide paths for electrical signals to the IC die; and
removing the tape from the substrate.

13. The method of forming a TBGA package of claim 12, wherein the substrate has a heat spreader attached thereto, wherein the through hole extends through the tape substrate and the heat spreader.

14. (canceled)

15. The method of forming a semiconductor package of claim 13, wherein the tape is attached to the heat spreader.

16. A method of forming a tape ball grid array (TBGA) package, comprising:
providing a substrate having a through hole formed therein;
attaching a tape to a surface of the substrate, wherein the through hole is covered by the tape;
attaching an integrated circuit (IC) die to an adhesive surface of the tape;
electrically connecting the IC die to the substrate via a plurality of electrical connections;
encapsulating the IC die and the electrical connections; and
removing the tape from the substrate, thereby exposing a portion of the IC die.

17. The method of forming a TBGA package of claim 16, further comprising attaching a heat sink to the exposed portion of the IC die.

18. The method of forming a TBGA package of claim 16, wherein the substrate comprises a tape substrate having a heat spreader attached thereto, wherein the through hole extends through the tape substrate and the heat spreader.

19. The method of forming a semiconductor package of claim 18, wherein the tape is attached to the tape substrate.

20. The method of forming a semiconductor package of claim 18, wherein the tape is attached to the heat spreader.
